(19) United States
(12) Patent Application Publication
(10) Pub. No.: US 2012/0153451 A1
(43) Pub. Date: Jun. 21, 2012

(54) SEMICONDUCTOR DEVICE

(75) Inventor: Yukimasa HAYASHIDA, Fukuoka (JP)

(73) Assignee: MITSUBISHI ELECTRIC CORPORATION, Chiyoda-ku (JP)

(21) Appl. No.: 13/178,952

(22) Filed: Jul. 8, 2011

(30) Foreign Application Priority Data
Dec. 21, 2010 (JP) 2010-284700

(51) Int. Cl. H01L 23/02

(52) U.S. Cl. 257/690; 257/E23.18

(57) ABSTRACT

A semiconductor device of the present invention comprises a semiconductor element, a main electrode connected to the semiconductor element, and a case for sealing the semiconductor element. The main electrode is provided, extending outside of the case from the inside thereof, and an external thread or an internal thread to be fastened to an external terminal is provided integrally on an extended portion of the main electrode, which extends outside of the case.

### BACKGROUND OF THE INVENTION

1. Field of the Invention

The present invention relates to a high power semiconductor device, and more particularly to a case portion of the semiconductor device.

2. Description of the Background Art

In an inverter device or the like, independently of a main apparatus (external application), used is a semiconductor device on which a high power semiconductor element is mounted. In such a semiconductor device, the semiconductor element is sealed inside a case.

In the semiconductor device, a main electrode electrically connected to the semiconductor element is formed, extending outside of the case. On the other hand, a nut is provided inside the case and a bolt electrically connected to an electrode on the side of the inverter is fastened to the nut through the main electrode. The main apparatus is thereby connected to the semiconductor device.

Japanese Patent Application Laid Open Gazette No. 2010-98036 (Patent Document 1) is an exemplary prior-art document showing a structure of a semiconductor device which allows the above-discussed fastening.

The fastening of the semiconductor device to the main apparatus is made by the nut outserted to the case, as discussed above. The fastening strength of the semiconductor device is held by the nut and the case, and the limitation of fastening conventionally depends on the endurance of the case against a break.

On the other hand, in recent, there has arisen a requirement for torque up of the fastening. The case is, however, made of PPS (Polyphenylene Sulfide) resin or the like and the PPS resin has a small fastening strength. Therefore, in order to prevent cracks and breaks of the case due to the fastening, there is a limitation on setting of the fastening torque.

### SUMMARY OF THE INVENTION

It is an object of the present invention to provide a semiconductor device which is capable of increasing a fastening torque in fastening the semiconductor device to a main apparatus without causing any damage to a case of the semiconductor device.

The present invention is intended for a semiconductor device. According to an aspect of the present invention, the semiconductor device includes a semiconductor element, a main electrode connected to the semiconductor element, and a case for sealing the semiconductor element. In the semiconductor device of the present invention, the main electrode is formed, extending outside of the case from the inside thereof, and an external thread or an internal thread to be fastened to an external terminal is provided integrally on an extended portion of the main electrode, which extends outside of the case.

Therefore, a force exerted in fastening the semiconductor device to the main apparatus is applied onto the main electrode made of a metal, not onto the case. It is thereby possible to increase a fastening torque in fastening the semiconductor device to the main apparatus without causing any damage to the case of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross section showing an overall structure of a semiconductor device;

FIG. 2 is an enlarged cross section showing a structure of a principal part (an extended portion of a main electrode and the vicinity thereof) of the semiconductor device in accordance with a first preferred embodiment;

FIG. 3 is an enlarged cross section showing a state before bending the extended portion of the main electrode;

FIG. 4 is an enlarged cross section showing a structure of a principal part (an extended portion of a main electrode and the vicinity thereof) of a semiconductor device in accordance with a second preferred embodiment; and

FIG. 5 is an enlarged cross section showing a structure of a principal part (an extended portion of a main electrode and the vicinity thereof) of a semiconductor device in accordance with a third preferred embodiment.

### DESCRIPTION OF THE PREFERRED EMBODIMENTS

Hereinafter, specific discussion will be made on the present invention, with reference to figures showing the preferred embodiments.

### The First Preferred Embodiment

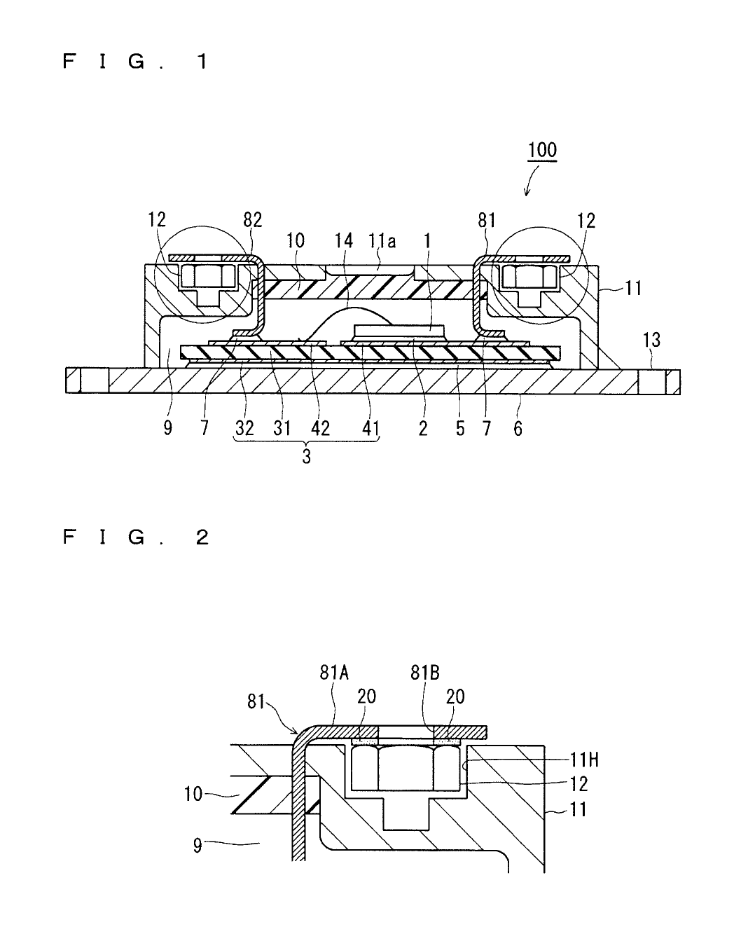

First, an outline of an overall structure of a semiconductor device will be discussed. FIG. 1 is a cross section showing an overall structure of a semiconductor device 100.

A semiconductor element 1 is bonded onto a substrate 3 with a solder 2. The substrate 3 consists of front surface electrodes 41 and 42, an insulating plate 31, and a back surface electrode 32.

Specifically, the front surface electrodes 41 and 42 are bonded onto a first main surface of the insulating plate 31 and the back surface electrode 32 is bonded onto a second main surface of the insulating plate 31. In the exemplary structure of FIG. 1, the semiconductor element 1 is bonded onto the front surface electrode 41 with the solder 2. The substrate 3 is bonded onto a base plate 6 with a solder 5, with the back surface electrode 32 interposed therebetween.

The semiconductor element 1 and the substrate 3 are covered with an insulating case 11.

As the case 11, for example, a molded article made of a plastic material such as PPS (i.e., a plastic product) may be used. The case 11 is provided with an opening 11a, and the inside of the case 11 is filled with a gel 9 supplied through the opening 11a in order to increase electrical insulation of the inside of the case 11. Further, the inside of the case 11 is filled with an epoxy resin 10 supplied through the opening 11a in order to increase moisture resistance of the inside of the case 11. An upper surface of the case 11 is sealed with the epoxy resin 10.

Further, in the exemplary structure of FIG. 1, an emitter electrode of the semiconductor element 1 is connected to the main electrode 81 through the front surface electrode 41 and a solder 7. A collector electrode of the semiconductor element 1 is connected to a main electrode 82 through an Aluminum wire 14, the front surface electrode 42, and the solder 7. Each of the main electrodes 81 and 82 is drawn (extended) from the inside of the case 11 to the outside thereof. As each of the electrodes 41, 42, 32, 81, and 82, a molded article made of a metal such as copper may be used.

In the semiconductor device 100 of the first preferred embodiment, an electrode of the main apparatus such as an inverter (more specifically, a bolt electrically connected to this electrode) is connected to a nut 12 through the main electrodes 81 and 82. The semiconductor element 1 of the semiconductor device 100 and an external circuit of the main apparatus are electrically connected to each other.

A not-shown radiator is screwed to the base plate 6 by using a mounting hole 13.

Hereinafter, discussion will be made on a specific structure of each of areas encircled in FIG. 1 and the vicinity thereof. Hereafter, though description will be made on the structure of the encircled area and the vicinity thereof on the side of the main electrode 81 in all the preferred embodiments including the first preferred embodiment, a similar description applies to the encircled area and the vicinity thereof on the side of the main electrode 82.

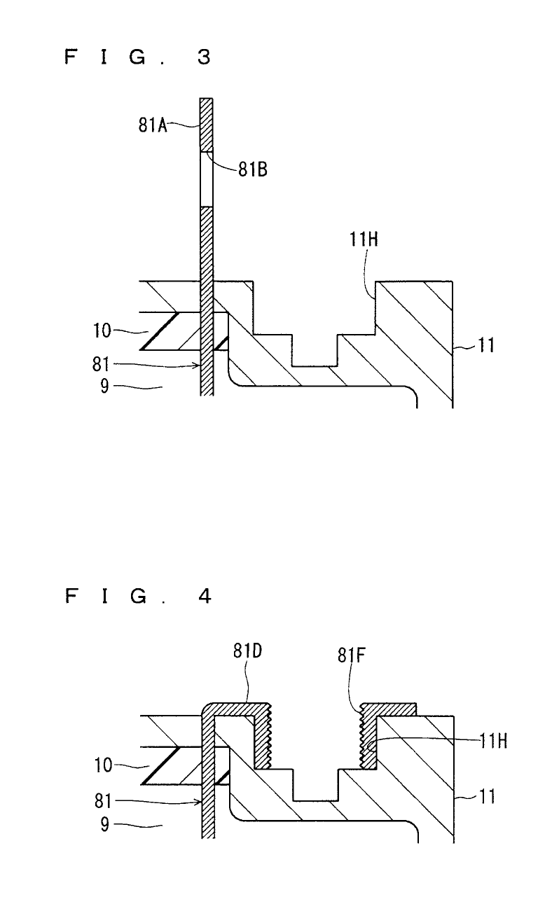

FIG. 2 is an enlarged cross section showing a structure of the main electrode 81 extending outside of the case 11 and the vicinity thereof in accordance with the first preferred embodiment.

As shown in FIG. 2, the main electrode 81 is formed, extending outside of the case 11 from the inside of the case 11. Herein, a portion of the main electrode 81 which extends outside of the case 11 is referred to as an extended portion 81A. The extended portion 81A of the main electrode 81 is so disposed as to face the upper surface portion of the case 11. In the extended portion 81A, formed is a hole 81B.

On the other hand, in the upper surface of the case 11 facing the extended portion 81A, a recess 11H is formed, as shown in FIG. 2. The nut 12 is provided (buried) by outserting inside the recess 11H of the case 11. The center of a hole (not shown) provided in the nut 12 and the center of the hole 81B provided in the extended portion 81A are substantially coincident with each other.

Further, in the first preferred embodiment, a lower surface of the extended portion 81A and an upper surface of the nut 12 are welded to each other. FIG. 2 shows this portion where the welding is performed, as a welded portion 20. In this structure, there is no welded portion 20 in an area where the hole 81B of the extended portion 81A faces the hole of the nut 12.

Next, discussion will be made on a method of manufacturing the structure shown in FIG. 2.

First, the resin case 11 having a desired shape is manufactured in advance. The manufactured case 11 is provided with the recess 11H in which the nut 12 is provided, the holes through which the main electrodes 81 and 82 can penetrate, the opening 11a, and the like.

On the other hand, in the structure of FIG. 1, the semiconductor element 1 is bonded onto the front surface electrode 41 of the substrate 3 with the solder 2 and the base plate 6 is bonded onto the back surface electrode 32 of the substrate 3 with the solder 5. Further, the front surface electrode 41 and the main electrode 81 are bonded to each other with the solder 7, to thereby connect the emitter electrode of the semiconductor element 1 to the main electrode 81. The semiconductor element 1 and the front surface electrode 42 are connected to each other with the Aluminum wire 14 and the front surface electrode 42 and the main electrode 82 are bonded to each other with the solder 7, to thereby connect the collector electrode of the semiconductor element 1 to the main electrode 82. The member manufactured in the process so far is referred to as a semiconductor element construct.

Next, the case 11 is so arranged as to cover the semiconductor element construct and the case 11 and the base plate 6 are bonded to each other. In the semiconductor element construct, the respective extended portions 81A of the main electrodes 81 and 82 arise from the lower side upward in FIG. 1. Therefore, the respective extended portions 81A of the main electrodes 81 and 82 penetrate through the holes provided in the case 11 while the case 11 is arranged as discussed above. In the state where the case 11 and the base plate 6 are bonded to each other, the respective extended portions 81A are projected out from the upper surface of the case 11, being upright.

Next, the inside of the case 11 is filled with the gel 9 which is supplied from the opening 11a formed in the case 11 and after that, the inside of the case 11 is filled with the epoxy resin 10 which is also supplied from the opening 11a. In the process so far, the semiconductor element construct is sealed with the case 11, and the epoxy resin 10, and the base plate 6. The structure of the extended portion 81A of the main electrode 81 and the vicinity thereof in the semiconductor device after sealing is enlargedly shown in the cross section of FIG. 3.

As shown in FIG. 3, the extended portion 81A is projected out from the upper surface of the case 11. In the extended portion 81A, the hole 81B is formed.

Next, in FIG. 3, the nut 12 is welded to the extended portion 81A. Specifically, in FIG. 3, a portion which is to become the upper surface of the nut 12 is overlaid onto the right side of the extended portion 81A. Herein, the center of the hole 81B of the extended portion 81A and the center of the hole of the nut 12 are substantially coincident with each other. The bolt provided in the inverter or the like is inserted into an overlapping portion of these holes. After the nut 12 is overlaid onto the extended portion 81A, the nut 12 and the extended portion 81A are welded to each other. The extended portion 81A and the nut 12 are thereby fixed to each other.

After that, the extended portion 81A with the nut 12 welded thereto is bent toward the recess 11H provided in the case 11. The extended portion 81A thereby faces the upper surface of the case 11 and the nut 12 welded to the extended portion 81A is housed in the recess 11H of the case 11. Naturally, the extended portion 81A may be brought into intimate contact with the upper surface of the case 11, unlike the structure shown in FIG. 2.

Thus, in the first preferred embodiment, the extended portion 81A of the main electrode 81 is welded to the nut 12 provided in the recess 11H of the case 11.

Therefore, the fastening strength in fastening the bolt connected to the electrode of the main apparatus and the nut 12 is held by the main electrode 81 which is a metal welded to the nut 12. In other words, the force exerted during the fastening is applied onto the main electrode 81 made of a metal, not onto the case 11 made of a resin. It is thereby possible to increase the fastening torque in fastening the semiconductor device 100 to the main apparatus without causing any damage to the case 11 of the semiconductor device 100.

### The Second Preferred Embodiment

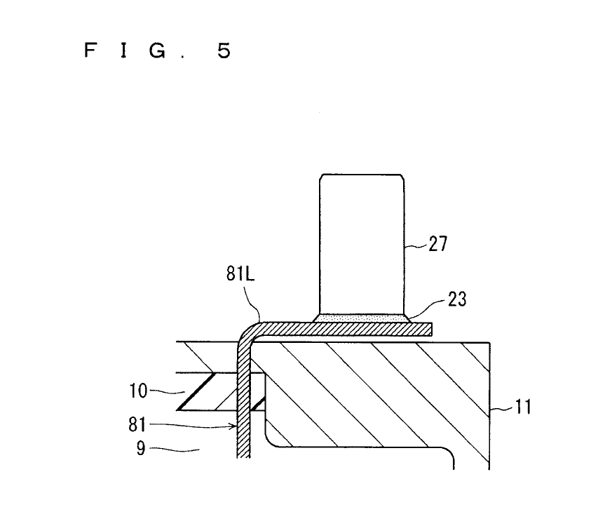

FIG. 4 is an enlarged cross section showing a structure of the main electrode 81 extending outside of the case 11 and the vicinity thereof in accordance with the second preferred embodiment.

As shown in FIG. 4, the main electrode 81 is formed, extending outside of the case 11 from the inside of the case 11. Herein, a portion of the main electrode 81 which extends outside of the case 11 is referred to as an extended portion 81D. The extended portion 81D of the main electrode 81 is so disposed as to face the upper surface portion of the case 11. In the upper surface of the case 11 facing the extended portion 81D, provided is the recess 11H, as shown in FIG. 4.

Further, in the second preferred embodiment, part of the extended portion 81D is formed, dropping down into the recess 11H of the case 11. Specifically, the extended portion 81D drawing out from the case 11 is provided first on the upper surface of the case 11, next on a side surface of the recess 11H, and then on another upper surface of the case 11. The extended portion 81D is formed on the side surface of the recess 11H as discussed above, and a screw thread (internal thread) 81F is formed on an exposed surface of part of the extended portion 81D which is provided on the side surface of the recess 11H. In a case where such a manufacturing method as discussed below is adopted, as shown in FIG. 4, no extended portion 81D is formed on a bottom surface of the recess 11H.

In the second preferred embodiment, no nut is provided inside the recess 11H of the case 11 and the extended portion 81D provided inside the recess 11H also performs the function of the nut 12 described in the first preferred embodiment (in other words, the bolt connected to the electrode of the main apparatus is fastened to the extended portion 81D provided inside the recess 11H).

Other than the shape of the extended portion 81D of the main electrode 81 and not providing the nut 12 inside the recess 11H of the case 11, the semiconductor device of the second preferred embodiment has the same structure as that of the semiconductor device of the first preferred embodiment. Therefore, description on the structure of the semiconductor device of the second preferred embodiment except that shown in FIG. 4 will be omitted.

Next, discussion will be made on a method of manufacturing the structure shown in FIG. 4.

First, the resin case 11 having a desired shape is manufactured in advance. The manufactured case 11 is provided with the recess 11H in which the extended portion 81D of the main electrode 81 is provided, the holes through which the main electrodes 81 and 82 can penetrate, the opening 11a, and the like.

On the other hand, in the structure of FIG. 1, the semiconductor element 1 is bonded onto the front surface electrode 41 of the substrate 3 with the solder 2 and the base plate 6 is bonded onto the back surface electrode 32 of the substrate 3 with the solder 5. Further, the front surface electrode 41 and the main electrode 81 are bonded to each other with the solder 7, to thereby connect the emitter electrode of the semiconductor element 1 to the main electrode 81. The semiconductor element 1 and the front surface electrode 42 are connected to each other with the Aluminum wire 14 and the front surface electrode 42 and the main electrode 82 are bonded to each other with the solder 7, to thereby connect the collector electrode of the semiconductor element 1 to the main electrode 82. The member manufactured in the process so far is referred to as a semiconductor element construct.

Next, the case 11 is so arranged as to cover the semiconductor element construct and the case 11 and the base plate 6 are bonded to each other. In the semiconductor element construct, the respective extended portions 81D of the main electrodes 81 and 82 arise from the lower side upward in FIG. 1. Therefore, the respective extended portions 81D of the main electrodes 81 and 82 penetrate through the holes provided in the case 11 while the case 11 is arranged as discussed above. In the state where the case 11 and the base plate 6 are bonded to each other, the respective extended portions 81D are projected out from the upper surface of the case 11, being upright.

Next, the inside of the case 11 is filled with the gel 9 which is supplied from the opening 11a formed in the case 11 and after that, the inside of the case 11 is filled with the epoxy resin 10 which is also supplied from the opening 11a. In the process so far, the semiconductor element construct is sealed with the case 11, and the epoxy resin 10, and the base plate 6. The structure of the extended portion 81D of the main electrode 81 and the vicinity thereof in the semiconductor device after sealing is the same as that enlargedly shown in the cross section of FIG. 3.

Like in the discussion with reference to FIG. 3, also in the second preferred embodiment, the extended portion 81D is projected out from the upper surface of the case 11. In the extended portion 81D, formed is a hole serving as a prepared hole in a burring process.

Next, the extended portion 81D is bent toward the recess 11H provided in the case 11. The extended portion 81D thereby faces the upper surface of the case 11. Herein, in the extended portion 81D which is bent, the center of the hole serving as the prepared hole and the center of the recess 11H are substantially coincident with each other.

After that, a tip of a tool used in the burring process abuts against the hole of the extended portion 81D, which serves as the prepared hole, and is pushed down toward the inside of the recess 11H (burring process). As shown in FIG. 4, the hole of the extended portion 81D, which serves as the prepared hole, is thereby spread out downwardly along the side surface inside the recess 11H (in other words, provided extending downwardly inside the recess 11H) and the screw thread 81F is formed on an exposed surface of part of the extended portion 81D which is provided extending downwardly on the recess 11H. Thus, in the burring process, the hole of the extended portion 81D, which serves as the prepared hole, is spread out and the vicinity of the hole serving as the prepared hole is extended downwardly, to thereby so form a cylindrical opening in the extended portion 81D as to expose the bottom surface of the recess 11H as shown in FIG. 4.

Thus, in the second preferred embodiment, the extended portion 81D of the main electrode 81 is formed, dropping down into the recess 11H of the case 11, and the screw thread 81F is provided on the extended portion 81D inside the recess 11H.

Therefore, the fastening strength in fastening the bolt connected to the electrode of the main apparatus and the extended portion 81D is held by the main electrode 81 which is a metal. In other words, the force exerted during the fastening is applied onto the main electrode 81 made of a metal, not onto the case 11 made of a resin. It is thereby possible to increase the fastening torque in fastening the semiconductor device 100 to the main apparatus without causing any damage to the case 11 of the semiconductor device 100.

### The Third Preferred Embodiment

FIG. 5 is an enlarged cross section showing a structure of the main electrode 81 extending outside of the case 11 and the vicinity thereof in accordance with the third preferred embodiment.

As shown in FIG. 5, the main electrode 81 is formed, extending outside of the case 11 from the inside of the case 11. Herein, a portion of the main electrode 81 which extends outside of the case 11 is referred to as an extended portion 81L. The extended portion 81L of the main electrode 81 is so disposed as to face the upper surface portion of the case 11.

In the third preferred embodiment, no recess 11H is formed in the upper surface of the case 11 which faces the extended portion 81L, unlike in the first and second preferred embodiments (no nut 12 described in the first preferred embodiment is provided, naturally, since no recess 11H is formed). Further, in the third preferred embodiment, neither hole 81B described in the first preferred embodiment nor prepared hole for burring described in the second preferred embodiment is formed in the extended portion 81L.

Further, in the third preferred embodiment, a bolt 27 is provided on an upper surface of the extended portion 81L, upwardly in FIG. 5. The contact portions of the extended portion 81L and the bolt 27 are welded to each other. In other words, a welded portion 23 is formed between the extended portion 81L and the bolt 27 in the third preferred embodiment.

In the semiconductor device of the third preferred embodiment, the bolt 27 welded to the extended portion 81L is fastened to the nut connected to the electrode of the main apparatus. Though not shown in FIG. 5, a screw thread (external thread) is formed on the bolt 27.

Other than the above-described structure, the semiconductor device of the third preferred embodiment has the same structure as that of the semiconductor device of the first preferred embodiment. Therefore, description on the structure of the semiconductor device of the third preferred embodiment except that shown in FIG. 5 will be omitted.

Next, discussion will be made on a method of manufacturing the structure shown in FIG. 5.

First, the resin case 11 having a desired shape is manufactured in advance. The manufactured case 11 is provided with the holes through which the main electrodes 81 and 82 can penetrate, the opening 11a, and the like.

On the other hand, in the structure of FIG. 1, the semiconductor element 1 is bonded onto the front surface electrode 41 of the substrate 3 with the solder 2 and the base plate 6 is bonded onto the back surface electrode 32 of the substrate 3 with the solder 5. Further, the front surface electrode 41 and the main electrode 81 are bonded to each other with the solder 7, to thereby connect the emitter electrode of the semiconductor element 1 to the main electrode 81. The semiconductor element 1 and the front surface electrode 42 are connected to each other with the Aluminum wire 14 and the front surface electrode 42 and the main electrode 82 are bonded to each other with the solder 7, to thereby connect the collector electrode of the semiconductor element 1 to the main electrode 82. The member manufactured in the process so far is referred to as a semiconductor element construct.

Next, the case 11 is so arranged as to cover the semiconductor element construct and the case 11 and the base plate 6 are bonded to each other. In the semiconductor element construct, the respective extended portions 81L of the main electrodes 81 and 82 arise from the lower side upward in FIG. 1. Therefore, the respective extended portions 81L of the main electrodes 81 and 82 penetrate through the holes provided in the case 11 while the case 11 is arranged as discussed above. In the state where the case 11 and the base plate 6 are bonded to each other, the respective extended portions 81L are projected out from the upper surface of the case 11, being upright.

Next, the inside of the case 11 is filled with the gel 9 which is supplied from the opening 11a formed in the case 11 and after that, the inside of the case 11 is filled with the epoxy resin 10 which is also supplied from the opening 11a. In the process so far, the semiconductor element construct is sealed with the case 11, and the epoxy resin 10, and the base plate 6. The structure of the extended portion 81L of the main electrode 81 and the vicinity thereof in the semiconductor device after sealing is the same as that enlargedly shown in the cross section of FIG. 3.

Like in the discussion with reference to FIG. 3, also in the third preferred embodiment, the extended portion 81L is projected out from the upper surface of the case 11. In the third preferred embodiment, however, no hole is formed in the extended portion 81L.

Next, the extended portion 81L is bent toward the upper surface of the case 11. The extended portion 81L thereby faces the upper surface of the case 11. Naturally, the extended portion 81L may be brought into intimate contact with the upper surface of the case 11, unlike the structure shown in FIG. 5.

After that, the bolt 27 is provided, being upright, on the extended portion 81L which is bent. Then, contact portions of the extended portion 81L and the bolt 27 are welded to each other. The welded portion 23 is thereby formed between the extended portion 81L and the bolt 27, and the bolt 27 is fixed onto the extended portion 81L.

Thus, in the third preferred embodiment, the bolt 27 is welded onto the extended portion 81L of the main electrode 81.

Therefore, the fastening strength in fastening the nut connected to the electrode of the main apparatus and the bolt 27 welded onto the extended portion 81L is held by the main electrode 81 which is a metal. In other words, the force exerted during the fastening is applied onto the main electrode 81 made of a metal, not onto the case 11 made of a resin. It is thereby possible to increase the fastening torque in fastening the semiconductor device 100 to the main apparatus without causing any damage to the case 11 of the semiconductor device 100.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor element;
a main electrode connected to said semiconductor element; and
a case for sealing said semiconductor element,
wherein said main electrode is formed, extending outside of said case from the inside thereof, and
an external thread or an internal thread to be fastened to an external terminal is provided integrally on an extended portion of said main electrode, which extends outside of said case.

2. The semiconductor device according to claim 1, wherein
said extended portion of said main electrode, which extends outside of said case, faces an upper surface portion of said case,
a recess is formed in said case facing said extended portion,
a nut is provided inside said recess of said case, and
said nut and said extended portion of said main electrode are welded to each other.

3. The semiconductor device according to claim 1, wherein
a recess is formed in said case,
said extended portion of said main electrode, which extends outside of said case, is provided, dropping down into said recess of said case, and
a screw thread is formed on part of said extended portion which drops down into said recess.

4. The semiconductor device according to claim 1, wherein
said extended portion of said main electrode, which extends outside of said case, faces an upper surface portion of said case,
a bolt is provided projectingly on said extended portion, and
said bolt and said extended portion are welded to each other.
